(19) United States
(12) Patent Application Publication
(10) Pub. No.: US 2015/0017392 A1
(43) Pub. Date: Jan. 15, 2015

(54) REFLECTIVE FILMS, ARTICLES AND METHODS OF MAKING THE SAME

(71) Applicant: 3M INNOVATIVE PROPERTIES COMPANY, St. Paul, MN (US)

(72) Inventors: Rajesh K. Katare, Cottage Grove, MN (US); Timothy J. Hebrink, Scandia, MN (US); Mark B. O'Neill, Stillwater, MN (US)

(73) Assignee: 3INNOVATIVE PROPERTIES COMPANY, St. Paul, MN (US)

(21) Appl. No.: 14/373,260

(22) PCT Filed: Jan. 15, 2013
(86) PCT No.: PCT/US2013/021545

§ 371 Date: Jul. 18, 2014

Related U.S. Application Data
(60) Provisional application No. 61/593,144, filed on Jan. 31, 2012.

(51) Int. Cl. C23C 30/00; C23C 14/12; C23C 14/22; B32B 15/08; C23C 28/00

(52) U.S. Cl. CPC C23C 30/00; B32B 15/08; C23C 28/00; C23C 14/22; C23C 14/12; B32B 2551/08; B32B 2255/10; B32B 2264/102; B32B 2307/416
USPC 428/174; 428/461; 428/336; 428/338; 428/448; 428/331; 428/329; 428/328; 427/162

(57) ABSTRACT

A reflective film or article including a substrate, a smoothing layer adjoining and extending across at least a portion of the first major surface of the substrate, a tie layer having a first major surface adjoining and extending across at least a portion of the second major surface of the substrate, and a metallic layer adjoining and extending across at least a portion of the second major surface of the tie layer. The smoothing layer includes poly(methyl methacrylate) and a first block copolymer having at least two endblock polymeric units and at least one midblock polymeric unit derived from first and second monoethylenically unsaturated monomers selected from a methacrylate, acrylate, vinyl ester, or combination thereof, respectively, each endblock having a glass transition temperature (T_{g}) of at least 50° C., and each endblock having a T_{g} no greater than 20° C.

### CROSS REFERENCE TO RELATED APPLICATIONS

This application claims the benefit of U.S. Provisional Application No. 61/593,144, filed Jan. 31, 2012, the disclosure of which is incorporated by reference herein in its entirety.

### TECHNICAL FIELD

The present disclosure relates to reflective films, articles incorporating such films, and related methods of manufacture. More particularly, the disclosed reflective films, articles and methods of manufacture may be used, for example, in cosmetic, packaging, lighting, and solar reflector applications.

### BACKGROUND

Renewable energy is energy derived from natural resources that can be replenished, such as sunlight, wind, rain, tides, and geothermal heat. The demand for renewable energy has grown substantially with advances in technology and increases in global population. Although fossil fuels provide for the vast majority of energy consumption today, these fuels are non-renewable. The global dependence on these fossil fuels has not only raised concerns about their depletion but also environmental concerns associated with emissions that result from burning these fuels.

As a result of these concerns, countries worldwide have been establishing initiatives to develop both large-scale and small-scale renewable energy resources. One of the promising energy resources today is sunlight. Globally, millions of households currently obtain power from solar photovoltaic systems.

Concentrated solar power plants collect solar radiation in order to directly or indirectly provide the hot side of an engine that is used to produce electricity. These systems use mirrored surfaces in multiple geometries, dictated by the design of the system. These geometries include flat mirrors, parabolic dishes and parabolic troughs, among others. These reflective surfaces concentrate sunlight onto a receiver. That, in turn, heats a working fluid (e.g. a synthetic oil or a molten salt). In some cases, the working fluid is what drives the engine that produces electricity, and in other cases, this working fluid is passed through a heat exchanger to produce steam, which is used to power a steam turbine to generate electricity.

Solar thermal systems collect solar radiation to heat water or to heat process streams in industrial processes. Some solar thermal designs make use of reflective mirrors to concentrate sunlight onto receivers that contain water or the feed stream. The principle of operation is very similar to concentrated solar power plants, but the concentration of sunlight and therefore the working temperatures are not as high.

The rising demand for solar thermal systems has been accompanied by rising demands for reflective devices and materials capable of fulfilling the requirements for these applications. Some of these solar reflector technologies include glass mirrors, aluminized mirrors, and metalized polymer films. Of these, metalized polymer films are particularly attractive because they are lightweight and offer design flexibility and potentially enable cheaper installed system designs than conventional glass mirrors.

Other important commercial applications for these reflective devices and materials include photovoltaic concentrators, natural lighting in building, digital signs, automotive applications such as headlight reflectors, and residential light reflectors. Metalized films can also be used for cosmetic applications, or for food packaging to prevent gases and light rays from degrading food products. Reflective film sheeting can also be used by museums and archival institutions to protect collectibles from damaging light rays.

### SUMMARY

In one aspect, the disclosure describes a multilayer reflective film or article including a substrate having a first major surface and a second major surface opposite the first major surface; a smoothing layer adjoining the first major surface of the substrate and extending across at least a portion of the first major surface of the substrate, wherein the smoothing layer is non-tacky at ambient temperatures and includes poly(methyl methacrylate) and a first block copolymer having at least two endblock polymeric units that are each derived from a first monoethylenically unsaturated monomer selected from a methacrylate, acrylate, styrene, or combination thereof, wherein each endblock has a glass transition temperature of at least 50 degrees Celsius; and at least one midblock polymeric unit that is derived from a second monoethylenically unsaturated monomer selected from a methacrylate, acrylate, vinyl ester, or combination thereof, wherein each midblock has a glass transition temperature no greater than 20 degrees Celsius; a tie layer adjoining and extending across at least a portion of the second major surface of the substrate, the tie layer having a first major surface adjoining the second major surface of the substrate, and a second major surface opposite the first major surface of the tie layer, wherein the tie layer includes a second block copolymer with at least two endblock polymeric units that are each derived from a first monoethylenically unsaturated monomer selected from a methacrylate, acrylate, styrene, or combination thereof, wherein each endblock has a glass transition temperature of at least 50 degrees Celsius; and at least one midblock polymeric unit that is derived from a second monoethylenically unsaturated monomer selected from a methacrylate, acrylate, vinyl ester, or combination thereof, wherein each midblock has a glass transition temperature no greater than 20 degrees Celsius; and

a metallic layer adjoining and extending across at least a portion of the second major surface of the tie layer.

In some exemplary embodiments, the article includes at least one additional block copolymer having endblocks including poly(methyl methacrylate) and a midblock including poly(butyl acrylate), wherein the at least one additional block copolymer is compositionally distinct from at least one of the first block copolymer or the second block copolymer, further wherein the at least one additional block copolymer is present in one or both of the smoothing layer and the tie layer.

In certain exemplary embodiments, at least one of the first block copolymer, the second block copolymer, or the at least one additional block copolymer contains an ultraviolet (UV) light absorber in an amount from 0.5 wt. % to 3.0 wt. %, based on the total weight of the first block copolymer and the UV light absorber, the second block copolymer and the UV light absorber, or the at least one additional block copolymer and the UV light absorber, respectively.

In additional exemplary embodiments of any of the foregoing, each endblock of at least one of the first block copolymer, the second block copolymer, or the at least one additional block copolymer is comprised of poly(methyl methacrylate), and further wherein each midblock of at least one of the first block copolymer or the second block copolymer is comprised of poly(butyl acrylate). In some exemplary embodiments, at least one of the first block copolymer, the second block copolymer, or the at least one additional block copolymer is comprised of from 30 wt. % to 80 wt. % endblocks, and from 20 wt. % to 70 wt. % midblocks, based on a total weight of the respective block copolymer. In certain particular exemplary embodiments, at least one of the first block copolymer, the second block copolymer, or the at least one additional block copolymer is comprised of from 50 wt. % to 70 wt. % endblocks, and from 30 wt. % to 50 wt. % midblocks, based on the total weight of the respective block copolymer. In any of the foregoing exemplary embodiments, the first block copolymer may be selected to be the same as the second block copolymer.

In some additional exemplary embodiments of any of the foregoing, the smoothing layer has a thickness no greater than 5 micrometers. In some such embodiments, the smoothing layer has a thickness of from 0.1 micrometer to 3 micrometers.

In any of the foregoing exemplary embodiments, the tie layer has a thickness no greater than 500 micrometers. In some such embodiments, the tie layer has a thickness of from 0.1 micrometer to 5 micrometers.

In any of the foregoing exemplary embodiments, the metallic layer has a thickness no greater than 500 nanometers. In some such embodiments, the metallic layer has a thickness of from 80 nm to 250 nm.

In any of the foregoing exemplary embodiments, the substrate has a thickness of from 25 micrometers to 500 micrometers.

In further exemplary embodiments of any of the foregoing, the tie layer further includes a metal oxide. In some exemplary embodiments, the metal oxide is selected from the group consisting of titanium dioxide, aluminum oxide, silicon dioxide, indium oxide, tin oxide, zinc oxide, zirconium oxide, and combinations thereof. In some particular exemplary embodiments, the metal oxide is comprised of a multiplicity of metal oxide nanoparticulates dispersed in the tie layer. In certain such embodiments, the multiplicity of metal oxide nanoparticulates exhibit a median particle diameter no greater than 200 nm. In some particular embodiments, the multiplicity of metal oxide nanoparticulates exhibit a median particle diameter of from 10 to 100 nm.

In additional exemplary embodiments of any of the foregoing, the metallic layer includes one or more metals selected from the group consisting of: silver, gold, aluminum, copper, nickel, and titanium. In some such embodiments, the metallic layer includes a silver layer contacting the tie layer and a copper layer adjacent to the silver layer opposite the tie layer. In certain such embodiments, the silver layer has a thickness from 70 to 130 nanometers, and the copper layer has a thickness from 20 to 40 nanometers.

In some particular exemplary embodiments of any of the foregoing, the article has an arcuate surface, and the metallic layer extends across at least a portion of the arcuate surface.

In another aspect, the disclosure describes a reflective article including a substrate having a first major surface and a second major surface opposite the first major surface; a smoothing layer extending across at least a portion of the first major surface of the substrate, wherein the smoothing layer is non-tacky at ambient temperatures and includes poly(methyl methacrylate) and a first block copolymer having at least two endblock polymeric units that are each derived from a first monoethylenically unsaturated monomer selected from a methacrylate, acrylate, styrene, or combination thereof, wherein each endblock has a glass transition temperature of at least 50 degrees Celsius; and at least one midblock polymeric unit that is derived from a second monoethylenically unsaturated monomer selected from a methacrylate, acrylate, vinyl ester, or combination thereof, wherein each midblock has a glass transition temperature no greater than 20 degrees Celsius; a tie layer, the tie layer having a first major surface extending across at least a portion of the second major surface of the substrate, and a second major surface opposite the first major surface of the tie layer, wherein the tie layer including a second block copolymer with at least two endblock polymeric units that are each derived from a first monoethylenically unsaturated monomer selected from a methacrylate, acrylate, styrene, or combination thereof, wherein each endblock has a glass transition temperature of at least 50 degrees Celsius; and at least one midblock polymeric unit that is derived from a second monoethylenically unsaturated monomer selected from a methacrylate, acrylate, vinyl ester, or combination thereof, wherein each midblock has a glass transition temperature no greater than 20 degrees Celsius; and a metallic layer extending across at least a portion of the second major surface of the tie layer.

In some exemplary embodiments, the metallic layer includes silver, and the reflective article exhibits a Specularity of at least 94% as measured using the Specularity Method defined herein.

In yet another aspect, the disclosure describes a method of making a reflective article, including providing a substrate having a first major surface and a second major surface opposite the first major surface; applying a smoothing layer to at least a portion of the first major surface of the substrate, wherein the smoothing layer is non-tacky at ambient temperatures and includes poly(methyl methacrylate) and a first block copolymer having at least two endblock polymeric units that are each derived from a first monoethylenically unsaturated monomer selected from a methacrylate, acrylate, styrene, or combination thereof, wherein each endblock has a glass transition temperature of at least 50 degrees Celsius; and at least one midblock polymeric unit that is derived from a second monoethylenically unsaturated monomer selected from a methacrylate, acrylate, vinyl ester, or combination thereof, wherein each midblock has a glass transition temperature no greater than 20 degrees Celsius; applying a tie layer to at least a portion of the second major surface of the substrate, the tie layer having a first major surface extending across at least a portion of the second major surface of the substrate, and a second major surface opposite the first major surface of the tie layer, wherein the tie layer includes a second block copolymer with at least two endblock polymeric units that are each derived from a first monoethylenically unsaturated monomer selected from a methacrylate, acrylate, styrene, or combination thereof, wherein each endblock has a glass transition temperature of at least 50 degrees Celsius; and at least one midblock polymeric unit that is derived from a second monoethylenically unsaturated monomer selected from a methacrylate, acrylate, vinyl ester, or combination thereof, wherein each midblock has a glass transition temperature no greater than 20 degrees Celsius; and applying a metallic layer to at least a portion of the second major surface of the tie layer.

In some exemplary embodiments, the first block copolymer is the same as the second block copolymer. In certain exemplary embodiments, the smoothing layer has a thickness no greater than 50 micrometers. In some particular exemplary embodiments, the smoothing layer has a thickness of from 0.1 micrometer to 10 micrometers. In some particular exemplary embodiments, applying the smoothing layer comprises physical vapor deposition (PVD) coating of the smoothing layer.

The exemplary films, articles and methods of the present disclosure, in some exemplary embodiments, advantageously provide a smoother outer (e.g. top) surface of the multilayer film or article incorporating the multilayer film. The exemplary films, articles and methods exhibit improved specular reflection (Specularity) at 15 mrad angle when used as a reflector, for example, as a reflector in solar thermal reflector systems.

Various aspects and advantages of exemplary embodiments of the disclosure have been summarized. The above Summary is not intended to describe each illustrated embodiment or every implementation of the present invention. The Drawings and the Detailed Description that follow more particularly exemplify certain preferred embodiments using the principles disclosed herein.

### BRIEF DESCRIPTION OF THE DRAWINGS

Exemplary embodiments of the present disclosure are further described with reference to the appended drawings, wherein:

FIG. 1 is a side view showing various layers of an exemplary reflective article according to various exemplary embodiments of the present disclosure.

While the above-identified drawing, which may not be drawn to scale, sets forth various embodiments of the present disclosure, other embodiments are also contemplated, as noted in the Detailed Description. In all cases, this disclosure describes the presently disclosed invention by way of representation of exemplary embodiments and not by express limitations. It should be understood that numerous other modifications and embodiments can be devised by those skilled in the art, which fall within the scope and spirit of this invention.

### DETAILED DESCRIPTION

As used in this specification and the appended embodiments, the singular forms “a”, “an”, and “the” include plural referents unless the content clearly dictates otherwise. Thus, for example, reference to fine fibers containing “a compound” includes a mixture of two or more compounds. As used in this specification and the appended embodiments, the term “or” is generally employed in its sense including “and/or” unless the content clearly dictates otherwise.

As used in this specification, the recitation of numerical ranges by endpoints includes all numbers subsumed within that range (e.g. 1 to 5 includes 1, 1.5, 2, 2.75, 3, 3.8, 4, and 5).

Unless otherwise indicated, all numbers expressing quantities or ingredients, measurement of properties and so forth used in the specification and embodiments are to be understood as being modified in all instances by the term “about.” Accordingly, unless indicated to the contrary, the numerical parameters set forth in the foregoing specification and attached listing of embodiments can vary depending upon the desired properties sought to be obtained by those skilled in the art utilizing the teachings of the present disclosure. At the very least, and not as an attempt to limit the application of the doctrine of equivalents to the scope of the claimed embodiments, each numerical parameter should at least be construed in light of the number of reported significant digits and by applying ordinary rounding techniques.

For the following Glossary of defined terms, these definitions shall be applied for the entire application, unless a different definition is provided in the claims or elsewhere in the specification.

### GLOSSARY

The term “polymer” or “(co)polymer” includes homopolymers and copolymers, as well as homopolymers or copolymers that may be formed in a miscible blend, e.g., by coextrusion or by reaction, including, e.g., transesterification. The term “copolymer” includes random, block and star (e.g. dendritic) copolymers.

The terms “(meth)acrylate,” “(meth)acrylic” or “(meth)acrylic-functional” include monomers that having one or more ethylenically unsaturated acrylic- and/or methacrylic-functional groups: e.g. -AC(O)C(R)═CH₂, preferably wherein A is O, S or NR; and R is a 1-24 carbon lower alkyl group, H, F or Si; and materials (e.g. (co)polymers) derived by polymerization of such monomers.

The term “molecularly same (co)polymer(s)” means (co)polymers that have essentially the same repeating molecular unit, but which may differ in molecular weight, method of manufacture, commercial form, and the like.

The term “crosslinked” (co)polymer refers to a (co)polymer whose molecular chains are joined together by covalent chemical bonds, usually via crosslinking molecules or groups, to form a network polymer. A crosslinked (co)polymer is generally characterized by insolubility, but may be swellable in the presence of an appropriate solvent.

By using the term “T_{g}”, we refer to the glass transition temperature of a cured (co)polymer when evaluated in bulk rather than in a thin film form. In instances where a polymer can only be examined in thin film form, the bulk form T_{g} can usually be estimated with reasonable accuracy. Bulk form T_{g} values usually are determined by evaluating the rate of heat flow vs. temperature using differential scanning calorimetry (DSC) to determine the onset of segmental mobility for the (co)polymer and the inflection point (usually a second-order transition) at which the polymer can be said to change from a glassy to a rubbery state. Bulk form T_{g} values can also be estimated using a dynamic mechanical thermal analysis (DMTA) technique, which measures the change in the modulus of the (co)polymer as a function of temperature and frequency of vibration.

By using the terms “visible light-transmissive” or “optically clear” with reference to a film or layer, we mean that the film or layer exhibits an average radiation transmission over the visible light portion of the radiation spectrum from 380 nm to 780 nm (Tᵥᵢₛ) of at least about 90%, measured along the normal axis, and more preferably, additionally exhibits an average radiation transmission of at least 90% over the solar radiation wavelength range from 380 nm to 3,000 nm (Tₛₒₗₐᵣ).

The term “metal” includes a pure or elemental metal or a metal alloy.

The term “ambient temperature(s)” or “room temperature(s)” refers to a temperature in the range of 20 degrees Celsius to 26 degrees Celsius.

The term “layer” means a single stratum formed between two major surfaces. A layer may exist internally within a single web, e.g., a single stratum formed with multiple strata in a single web having first and second major surfaces defining the thickness of the web. A layer may also exist in a composite article comprising multiple webs, e.g., a single stratum in a first web having first and second major surfaces defining the thickness of the web, when that web is overlaid or underlaid by a second web having first and second major surfaces defining the thickness of the second web, in which case each of the first and second webs forms at least one layer. In addition, layers may simultaneously exist within a single web and between that web and one or more other webs, each web forming a layer.

The term “adjoining” with reference to a particular first layer means joined with or attached to another, second layer, in a position wherein the first and second layers are either next to (i.e., adjacent to) and directly contacting each other, or contiguous with each other but not in direct contact (i.e., there are one or more additional layers intervening between the first and second layers).

By using terms of orientation such as “atop”, “on”, “covering”, “uppermost”, “underlying” and the like for the location of various elements in the disclosed coated articles, we refer to the relative position of an element with respect to a horizontally-disposed, upwardly-facing substrate. It is not intended that the substrate or articles should have any particular orientation in space during or after manufacture.

By using the term “overcoated” to describe the position of a layer with respect to a substrate or other element of a film of this disclosure, we refer to the layer as being atop the substrate or other element, but not necessarily contiguous to either the substrate or the other element.

By using the term “separated by” to describe the position of a polymer layer with respect to two inorganic barrier layers, we refer to the polymer layer as being between the inorganic barrier layers but not necessarily contiguous to either inorganic barrier layer.

Various exemplary embodiments of the disclosure will now be described with particular reference to the Drawings. Exemplary embodiments of the invention may take on various modifications and alterations without departing from the spirit and scope of the disclosure. Accordingly, it is to be understood that the embodiments of the invention are not to be limited to the following described exemplary embodiments, but is to be controlled by the limitations set forth in the claims and any equivalents thereof.

### Reflective Films

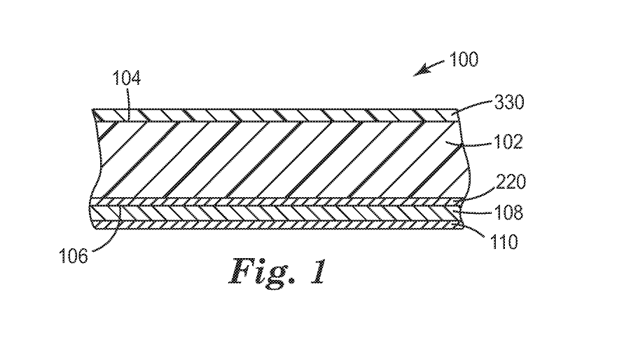

Provided herein are reflective multilayer films, related articles and methods of manufacturing the same. A reflective article according to one embodiment is shown in FIG. 1 and broadly denoted by the numeral 100. As shown, the article 100 includes a base layer (i.e. substrate) 102 having a first major surface 104 and a second major surface 106. A smoothing layer 330 contacts and extends across at least a portion of the first major surface 104. A tie layer 220 contacts and extending across the second surface 106 of the base layer 102, and successive metallic layers 108,110 extend across an opposing surface 106 of the tie layer 220. An optional adhesive layer (not shown in the drawings) may contact and extend across a metal layer 110 as shown in FIG. 1.

### (Smoothing) Layer (330)

The multilayer film or article 100 includes a smoothing layer that is non-tacky at ambient temperatures. The smoothing layer comprises poly(methyl methacrylate) and a first block copolymer having at least two endblock polymeric units that are each derived from a first monoethylenically unsaturated monomer comprising a methacrylate, acrylate, styrene, or combination thereof, wherein each endblock has a glass transition temperature of at least 50 degrees Celsius; and at least one midblock polymeric unit that is derived from a second monoethylenically unsaturated monomer comprising a methacrylate, acrylate, vinyl ester, or combination thereof, wherein each midblock has a glass transition temperature no greater than 20 degrees Celsius.

In some additional exemplary embodiments of any of the foregoing, the smoothing layer has a thickness no greater than 5 micrometers. In some such embodiments, the smoothing layer has a thickness of from 0.1 micrometer to 3 micrometers.

### Substrates or Base Layers (102)

Suitable substrates generally share certain characteristics. First, the substrate should be sufficiently smooth that texture in the substrate is not transmitted through the adhesive/metal/polymer stack. This, in turn, is advantageous because it: (1) allows for an optically accurate mirror, (2) maintains physical integrity of the metal by eliminating channels for ingress of reactive species that might corrode the metal or degrade the adhesive, and (3) provides controlled and defined stress concentrations within the reflective film-substrate stack. Second, the substrate is preferably nonreactive with the reflective mirror stack to prevent corrosion. Third, the substrate preferably has a surface to which the adhesive durably adheres.

In any of the exemplary embodiments of this disclosure, the substrate has a thickness of from 25 micrometers to 500 micrometers.

Exemplary substrates for reflective films, along with associated options and advantages, are described in PCT Publication Nos. WO04114419 (Schripsema), and WO03022578 (Johnston et al.); U.S. Publication Nos. 2010/0186336 (Valente, et al.) and 2009/0101195 (Reynolds, et al.); and U.S. Pat. No. 7,343,913 (Neidermeyer).

### Tie Layer (220)

In exemplary embodiments, the tie layer 220 comprises a triblock copolymer that is non-tacky (non-adhesive) at ambient temperatures. The block copolymer has at least two endblock polymeric units, each derived from a first monoethylenically unsaturated monomer comprising a methacrylate, acrylate, styrene, or combination thereof. The block copolymer has one midblock polymeric unit that is derived from a second monoethylenically unsaturated monomer comprising a methacrylate, acrylate, vinyl ester, or combination thereof. Each endblock has a glass transition temperature of at least 50 degrees Celsius, while the midblock has a glass transition temperature no greater than 20 degrees Celsius.

The tie layer 220 may alternatively comprise a block copolymer/homopolymer blend. For example, the base layer 102 may include an A-B-A triblock copolymer blended with a homopolymer that is soluble in either the A or B block. Optionally, the homopolymer has a polymeric unit identical to either the A or B block. The addition of one or more homopolymers to the block copolymer composition can be advantageously used either to plasticize or to harden one or both blocks. In preferred embodiments, the block copolymer contains a poly(methyl methacrylate) A block and a poly(butyl acrylate) B block, and is blended with a poly(methyl methacrylate) homopolymer.

Advantageously, blending poly(methyl methacrylate) homopolymer with poly(methyl methacrylate)-poly(butyl acrylate) block copolymers allows the hardness of the base layer 102 to be tailored to the desired application. As a further advantage, blending with poly(methyl methacrylate) provides this control over hardness without significantly degrading the clarity or processability of the overall composition. Preferably, the homopolymer/block copolymer blend has an overall poly(methyl methacrylate) composition of at least 30 percent, at least 40 percent, or at least 50 percent, based on the overall weight of the blend. Preferably, the homopolymer/block copolymer blend has an overall poly(methyl methacrylate) composition no greater than 95 percent, no greater than 90 percent, or no greater than 80 percent, based on the overall weight of the blend.

Particularly suitable non-tacky block copolymers include poly(methyl methacrylate)-poly(n-butyl acrylate)-poly(methyl methacrylate) (25:50:25) triblock copolymers. These materials were previously available under the trade designation LA POLYMER from Kuraray Co., LTD, and are available as of the filing date of this application under the brand name KURARITY from the same company, as of August 2010.

Optionally, the block copolymer may be combined with a suitable ultraviolet light absorber to enhance the stability of the base layer 102. In some embodiments, the block copolymer contains an ultraviolet light absorber. In some embodiments, the block copolymer contains an amount of the ultraviolet light absorber ranging from 0.5 percent to 3.0 percent by weight, based on the total weight of the block copolymer and absorber. It is to be noted, however, that the block copolymer need not contain any ultraviolet light absorbers. Using a composition free of any ultraviolet light absorbers can be advantageous because these absorbers can segregate to the surfaces of the base layer 102 and interfere with adhesion to adjacent layers.

As a further option, the block copolymer may be combined with one or more nanofillers to adjust the modulus of the tie layer 220. For example, a nanofiller such as silicon dioxide or zirconium dioxide can be uniformly dispersed in the block copolymer to increase the overall stiffness or hardness of the article 100. In preferred embodiments, the nanofiller is surface-modified as to be compatible with the polymer matrix. This can help avoid making porous materials that scatter light upon tentering.

The tie layer 220 may also comprise a random copolymer having a first polymeric unit with a relatively high T_{g} and second polymeric unit with a relatively low T_{g}. In this embodiment, the first polymeric unit derives from a first monoethylenically unsaturated monomer comprising a methacrylate, acrylate, styrene, or combination thereof and associated with a glass transition temperature of at least 50 degrees Celsius and the second polymeric unit derived from a second monoethylenically unsaturated monomer comprising a methacrylate, acrylate, vinyl ester, or combination thereof and associated with a glass transition temperature no greater than 20 degrees Celsius.

In particularly preferred random copolymers, the first polymeric unit is methyl methacrylate and the second polymeric unit is butyl acrylate. It is preferable that the random copolymer has a methyl methacrylate composition of at least 50 percent, at least 60 percent, at least 70 percent, or at least 80 percent, based on the overall weight of the random copolymer. It is further preferable that the random copolymer has a methyl methacrylate composition of at most 80 percent, at most 85 percent, at most 90 percent, or at most 95 percent, based on the overall weight of the random copolymer.

In some embodiments, the tie layer 220 has a thickness of at least 10 micrometers, at least 50 micrometers, or at least 60 micrometers. Additionally, in some embodiments, the tie layer 220 has a thickness no greater than 200 micrometers, no greater than 150 micrometers or no greater than 100 micrometers.

The multilayer film article includes a tie layer 220 interposed between the second surface 106 of the base layer 202 and a first surface of the uppermost metallic layer 108. In some embodiments, the tie layer 220 comprises a metal oxide such as aluminum oxide, copper oxide, titanium dioxide, silicon dioxide, or combinations thereof. As a tie layer 220, titanium dioxide was found to provide surprisingly high resistance to delamination in dry peel and wet peel testing. Further options and advantages of metal oxide tie layers are described in U.S. Pat. No. 5,361,172 (Schissel et al.).

In any of the foregoing exemplary embodiments, the tie layer has a thickness no greater than 500 micrometers. In some such embodiments, the tie layer has a thickness of from 0.1 micrometer to 5 micrometers. It is preferable that the tie layer 220 has an overall thickness of at least 0.1 nanometers, at least 0.25 nanometers, at least 0.5 nanometers, or at least 1 nanometer. It is further preferable that the tie layer 220 has an overall thickness no greater than 2 nanometers, no greater than 5 nanometers, no greater than 7 nanometers, or no greater than 10 nanometers.

### Metal Layer(s) (108, 110)

Extending across the second surface 106 of the base (substrate) layer 102 is a metallic layer 108. In exemplary embodiments, the metallic layer 108 comprises elemental silver. As noted, however, other metals such as aluminum can also be used. Preferably, the interface between the metallic layer 108 and the base layer 102 is sufficiently smooth that the metallic layer 108 provides a specular (mirrored) surface.

The metallic layer 108 need not extend across the entire second surface 106 of the base layer 102. If desired, the base layer 102 can be masked during the deposition process such that the metallic layer 108 is applied onto only a pre-determined portion of the base layer 102. Patterned deposition of the metallic layer 108 onto the base layer 102 is also possible.

Optionally and as shown, a second metallic layer 110 contacts and extends across the first metallic layer 108. In exemplary embodiments, the second metallic layer 110 comprises elemental copper. Use of a copper layer that acts as a sacrificial anode can provide a reflective article with enhanced corrosion-resistance and outdoor weatherability. As another approach, a relatively inert metal alloy such as Inconel (an iron-nickel alloy) can also be used to enhance corrosion resistance.

The reflective metal layer is preferably thick enough to reflect the desired amount of the solar spectrum of light. The preferred thickness can vary depending on the composition of the metallic layer 108,110. For example, the metallic layer 108,110 is preferably at least about 75 nanometers to about 100 nanometers thick for metals such as silver, aluminum, and gold, and preferably at least about 20 nanometers or at least about 30 nanometers thick for metals such as copper, nickel, and titanium.

In any of the foregoing exemplary embodiments, the metallic layer has a thickness no greater than 500 nanometers. In some such embodiments, the metallic layer has a thickness of from 80 nm to 250 nm. In some embodiments, one or both of the metallic layers 108,110 have a thickness of at least 25 nanometers, at least 50 nanometers, at least 75 nanometers, at least 90 nanometers, or at least 100 nanometers. Additionally, in some embodiments, one or both of the metallic layers 108,110 have a thickness no greater than 100 nanometers, no greater than 110 nanometers, no greater than 125 nanometers, no greater than 150 nanometers, no greater than 200 nanometers, no greater than 300 nanometers, no greater than 400 nanometers, or no greater than 500 nanometers.

As described previously, one or both of the metallic layers 108,110 can be deposited using any of a number of methods known in the art, including chemical vapor deposition, physical vapor deposition, and evaporation. Although not shown in the figures, three or more metallic layers may be used.

### Optional Adhesive Layer

Optionally, the reflective film or article 100 is adhered to a supporting substrate or back plate (not shown in the drawing) to impart a suitable shape to the reflective article 100. Reflective article 100 can be adhered to a substrate using, for example, a suitable adhesive. In some embodiments, the adhesive is a pressure sensitive adhesive. As used herein, the term “pressure sensitive adhesive” refers to an adhesive that exhibits aggressive and persistent tack, adhesion to a substrate with no more than finger pressure, and sufficient cohesive strength to be removable from the substrate. Exemplary pressure sensitive adhesives include those described in PCT Publication No. WO 2009/146227 (Joseph, et al.).

### Optional Release Liner

As a further option not shown in the drawings, the substrate may include a release surface to allow the reflective article 100 and pressure sensitive adhesive to be easily removed and transferred to another substrate. For example, the exposed surface of the metallic layer 110 in FIG. 1 may be coated with a pressure sensitive adhesive and the pressure sensitive adhesive temporarily secured to a silicone-coated release liner. Such a configuration can then be conveniently packaged for transport, storage, and consumer use.

In some exemplary embodiments, the disclosure provides reflective articles that include at least one of the block copolymers or random copolymer compositions described above, along with a metallic composition forming a layer within the reflective article.

### Reflective Film Components

### Block Copolymers

In some embodiments, the provided reflective articles have a non-tacky base layer that includes one or more block copolymers.

As used herein, the term “block copolymer” refers to a polymeric material that includes a plurality of distinct polymeric segments (or “blocks”) that are covalently bonded to each other. A block copolymer includes (at least) two different polymeric blocks, commonly referred to as the A block and the B block. The A block and the B block generally have chemically dissimilar compositions with different glass transition temperatures.

Further, each of the A and B blocks includes a plurality of respective polymeric units. The A block polymeric units, as well as the B block polymeric units, are generally derived from monoethylenically unsaturated monomers. Each polymeric block and the resulting block copolymer have a saturated polymeric backbone without the need for subsequent hydrogenation.

An “ABA” triblock copolymer has a pair of A endblocks covalently coupled to a B midblock. As used herein, the term “endblock” refers to the terminal segments of the block copolymer and the term “midblock” refers to the central segment of the block copolymer. The terms “A block” and “A endblock” are used interchangeably herein. Likewise, the terms “B block” and “B midblock” are used interchangeably herein.

The block copolymer with at least two A block and a least one B block can also be a star block copolymer having at least three segments of formula (A-B)-. Star block copolymers often have a central region from which various branches extend. In these cases, the B blocks are typically in the central regions and the A blocks are in the terminal regions of the star block copolymers.

In preferred embodiments, the A blocks are more rigid than the B block. That is, the A blocks have a higher glass transition temperature and have a higher hardness than that of the B block. As used herein, the term “glass transition temperature,” or “T_{g},” refers to the temperature at which a polymeric material undergoes a transition from a glassy state to a rubbery state. The glassy state is typically associated with a material that is, for example, brittle, stiff, rigid, or a combination thereof. In contrast, the rubbery state is typically associated with a material that is flexible and/or elastomeric. The B block is commonly referred to as a soft block while the A blocks are referred to as hard blocks.

The glass transition temperature can be determined using a method such as Differential Scanning Calorimetry (DSC) or Dynamic Mechanical Analysis (DMA). Preferably, the A blocks have a glass transition temperature of at least 50 degrees Celsius and the B block has a glass transition temperature no greater than 20 degrees Celsius. In exemplary block copolymers, the A blocks have a T_{g} of at least 60 degrees Celsius, at least 80 degrees Celsius, at least 100 degrees Celsius, or at least 120 degrees Celsius while the B block has a glass transition temperature no greater than 10 degrees Celsius, no greater than 0 degrees Celsius, no greater than −5 degrees Celsius, or no greater than −10 degrees Celsius.

In some embodiments, the A block component is a thermoplastic material while the B block component is an elastomeric material. As used herein, the term “thermoplastic” refers to a polymeric material that flows when heated and that returns to its original state when cooled back to room temperature. As used herein, the term “elastomeric” refers to a polymeric material that can be stretched to at least twice its original length and then retracted to approximately its original length upon release.

The solubility parameter of the A blocks is preferably substantially different from the solubility parameter of the B block. Stated differently, the A blocks are typically not compatible or miscible with the B block, and this generally results in localized phase separation, or “microphase separation”, of the A and B blocks. Microphase separation can advantageously impart elastomeric properties and dimensional stability to a block copolymer material.

In some embodiments, the block copolymer has a multiphase morphology, at least at temperatures in the range of about 20 degrees Celsius to 150 degrees Celsius. The block copolymer can have distinct regions of reinforcing A block domains (e.g., nanodomains) in a matrix of the softer, elastomeric B block. For example, the block copolymer can have a discrete, discontinuous A block phase in a substantially continuous B block phase. In some such examples, the concentration of A block polymeric units is no greater than about 35 weight percent of the block copolymer. The A blocks usually provide the structural and cohesive strength for the block copolymer.

The monoethylenically unsaturated monomers that are suitable for the A block polymeric units preferably have a T_{g} of at least 50 degrees Celsius when reacted to form a homopolymer. In many examples, suitable monomers for the A block polymeric units have a T_{g} of at least 60 degrees Celsius, at least 80 degrees Celsius, at least 100 degrees Celsius, or at least 120 degrees Celsius when reacted to form a homopolymer. The T_{g} of these homopolymers can be up to 200 degrees Celsius or up to 150 degrees Celsius. The T_{g} of these homopolymers can be, for example, in the range of 50 degrees Celsius to 200 degrees Celsius, 50 degrees Celsius to 150 degrees Celsius, 60 degrees Celsius to 150 degrees Celsius, 80 degrees Celsius to 150 degrees Celsius, or 100 degrees Celsius to 150 degrees Celsius. In addition to these monomers having a T_{g} of at least 50 degrees Celsius when reacted to form a homopolymer, other monomers can be optionally included in the A block while the T_{g} of the A block remains at least 50 degrees Celsius.

The A block polymeric units may be derived from methacrylate monomers, styrenic monomers, or a mixture thereof. That is, the A block polymeric units may be the reaction product of a monoethylenically unsaturated monomer that is selected from a methacrylate monomer, styrenic monomer, or mixture thereof.

As used herein to describe the monomers used to form the A block polymeric units, the term “mixture thereof” means that more than one type of monomer (e.g., a methacrylate and styrene) or more than one of the same type of monomer (e.g., two different methacrylates) can be mixed. The at least two A blocks in the block copolymer can be the same or different. In many block copolymers all of the A block polymeric units are derived from the same monomer or monomer mixture.

In some embodiments, methacrylate monomers are reacted to form the A blocks. That is, the A blocks are derived from methacrylate monomers. Various combinations of methacrylate monomers may be used to provide an A block having a T_{g} of at least 50 degrees Celsius. The methacrylate monomers can be, for example, alkyl methacrylates, aryl methacrylates, or aralkyl methacrylate of Formula (I).

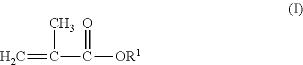

In Formula (I), R(1) is an alkyl, aryl, or aralkyl (i.e., an alkyl substituted with an aryl group).

Suitable alkyl groups often have 1 to 6 carbon atoms, 1 to 4 carbon atoms, or 1 to 3 carbon atoms. When the alkyl group has more than 2 carbon atoms, the alkyl group can be branched or cyclic. Suitable aryl groups often have 6 to 12 carbon atoms. Suitable aralkyl groups often have 7 to 18 carbon atoms.

Exemplary alkyl methacrylates according to Formula (I) include, but are not limited to, methyl methacrylate, ethyl methacrylate, isopropyl methacrylate, isobutyl methacrylate, tert-butyl methacrylate, and cyclohexyl methacrylate. In addition to the monomers of Formula (I), isobornyl methacrylate can be used. Exemplary aryl (meth)acrylates according to Formula (I) include, but are not limited to, phenyl methacrylate. Exemplary aralkyl methacrylates according to Formula (I) include, but are not limited to, benzyl methacrylate and 2-phenoxyethyl methacrylate.

In other embodiments, the A block polymeric units are derived from styrenic monomers. Exemplary styrenic monomers that can be reacted to form the A blocks include, but are not limited to, styrene, alpha-methylstyrene, and various alkyl substituted styrenes such as 2-methylstyrene, 4-methylstyrene, ethylstyrene, tert-butylstyrene, isopropylstyrene, and dimethylstyrene.

In addition to the monomers described above for the A blocks, these polymeric units can be prepared using up to 5 weight percent of the polar monomer such as methacrylamide, N-alkyl methacrylamide, N,N-dialkyl methacrylamide, or hydroxyalkyl methacrylate. These polar monomers can be used, for example, to adjust the cohesive strength of the A block and the glass transition temperature. Preferably, the T_{g} of each A block remains at least 50 degrees Celsius even with the addition of the polar monomer. Polar groups resulting from the polar monomers in the A block can function as reactive sites for chemical or ionic crosslinking, if desired.

The A block polymeric units can be prepared using up to 4 weight percent, up to 3 weight percent, or up to 2 weight percent of the polar monomer. In many examples, however, the A block polymeric units are substantially free or free of a polar monomer. As used herein, the term “substantially free” in reference to the polar monomer means that any polar monomer that is present is an impurity in one of the selected monomers used to form the A block polymeric units.

The amount of polar monomer is less than 1 weight percent, less than 0.5 weight percent, less than 0.2 weight percent, or less than 0.1 weight percent of the monomers in the reaction mixture used to form the A block polymeric units.

The A block polymeric units are often homopolymers. In exemplary A blocks, the polymeric units are derived from an alkyl methacrylate monomers with the alkyl group having 1 to 6, 1 to 4, 1 to 3, 1 to 2, or 1 carbon atom. In some more specific examples, the A block polymeric units are derived from methyl methacrylate (i.e., the A blocks are poly(methyl methacrylate)).

The monoethylenically unsaturated monomers that are suitable for use in the B block polymeric unit usually have a T_{g} no greater than 20 degrees Celsius when reacted to form a homopolymer. In many examples, suitable monomers for the B block polymeric unit have a T_{g} no greater than 10 degrees Celsius, no greater than 0 degrees Celsius, no greater than −5 degrees Celsius, or no greater than −10 degrees Celsius when reacted to form a homopolymer.

The T_{g} of these homopolymers is often at least −80 degrees Celsius, at least −70 degrees Celsius, at least −60 degrees Celsius, or at least −50 degrees Celsius. The T_{g} of these homopolymers can be, for example, in the range of −80 degrees Celsius to 20 degrees Celsius, −70 degrees Celsius to 10 degrees Celsius, −60 degrees Celsius to 0 degrees Celsius, or −60 degrees Celsius to −10 degrees Celsius. In addition to these monomers having a T_{g} no greater than 20 degrees Celsius when reacted to form a homopolymer, other monomers can be included in the B block while keeping the T_{g} of the B block no greater than 20 degrees Celsius.

The B midblock polymeric unit is typically derived from (meth)acrylate monomers, vinyl ester monomers, or a combination thereof. That is, the B midblock polymeric unit is the reaction product of a second monomer selected from (meth)acrylate monomers, vinyl ester monomers, or mixtures thereof. As used herein, the term “(meth)acrylate” refers to both methacrylate and acrylate. More than one type of monomer (e.g., a (meth)acrylate and a vinyl ester) or more than one of the same type of monomer (e.g., two different (meth)acrylates) can be combined to form the B midblock polymeric unit.

In many embodiments, acrylate monomers are reacted to form the B block. The acrylate monomers can be, for example, an alkyl acrylate or a heteroalkyl acrylate. The B blocks are often derived from acrylate monomers of Formula (II).

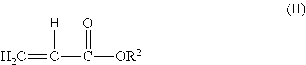

In Formula (II), R² is an alkyl with 1 to 22 carbons or a heteroalkyl with 2 to 20 carbons and 1 to 6 heteroatoms selected from oxygen or sulfur.

The alkyl or heteroalkyl group can be linear, branched, cyclic, or a combination thereof. Exemplary alkyl acrylates of Formula (II) that can be used to form the B block polymeric unit include, but are not limited to, ethyl acrylate, n-propyl acrylate, n-butyl acrylate, isobutyl acrylate, t-butyl acrylate, n-pentyl acrylate, isoamyl acrylate, n-hexyl acrylate, 2-methylbutyl acrylate, 2-ethylhexyl acrylate, 4-methyl-2-pentyl acrylate, n-octyl acrylate, isooctyl acrylate, isononyl acrylate, decyl acrylate, isodecyl acrylate, lauryl acrylate, isotridecyl acrylate, octadecyl acrylate, and dodecyl acrylate. Exemplary heteroalkyl acrylates of Formula (II) that can be used to form the B block polymeric unit include, but are not limited to, 2-methoxyethyl acrylate and 2-ethoxy ethyl acrylate.

Some alkyl methacrylates can be used to prepare the B blocks such as alkyl methacrylates having an alkyl group with greater than 6 to 20 carbon atoms. Exemplary alkyl methacrylates include, but are not limited to, 2-ethylhexyl methacrylate, isooctyl methacrylate, n-octyl methacrylate, isodecyl methacrylate, and lauryl methacrylate. Likewise, some heteroalkyl methacrylates such as 2-ethoxy ethyl methacrylate can also be used.

Polymeric units suitable for the B block can be prepared from monomers according to Formula (II). (Meth)acrylate monomers that are commercially unavailable or that cannot be polymerized directly can be provided through an esterification or trans-esterification reaction. For example, a (meth)acrylate that is commercially available can be hydrolyzed and then esterified with an alcohol to provide the (meth)acrylate of interest. Alternatively, a higher alkyl (meth)acrylate can be derived from a lower alkyl (meth)acrylate by direct trans-esterification of the lower alkyl (meth)acrylate with a higher alkyl alcohol.

In still other embodiments, the B block polymeric unit is derived from vinyl ester monomers. Exemplary vinyl esters include, but are not limited to, vinyl acetate, vinyl 2-ethyl-hexanoate, and vinyl neodecanoate.

In addition to the monomers described above for the B block, this polymeric unit can be prepared using up to 5 weight percent of the polar monomer such as acrylamide, N-alkyl acrylamide (e.g., N-methyl acrylamide), N,N-dialkyl acrylamide (N,N-dimethyl acrylamide), or hydroxyalkyl acrylate. These polar monomers can be used, for example, to adjust the glass transition temperature, while keeping the T_{g} of the B block less than 20 degrees Celsius. Additionally, these polar monomers can result in polar groups within the polymeric units that can function as reactive sites for chemical or ionic crosslinking, if desired.

The polymeric units can be prepared using up to 4 weight percent, up to 3 weight percent, up to 2 weight percent of the polar monomer. In other embodiments, the B block polymeric unit is free or substantially free of a polar monomer. As used herein, the term “substantially free” in reference to the polar monomer means that any polar monomer that is present is an impurity in one of the selected monomers used to form the B block polymeric unit.

Preferably, the amount of polar monomer is less than 1 weight percent, less than 0.5 weight percent, less than 0.2 weight percent, or less than 0.1 weight percent of the monomers used to form the B block polymeric units.

The B block polymeric unit may be a homopolymer. In some examples of the B block, the polymeric unit can be derived from an alkyl acrylate having an alkyl group with 1 to 22, 2 to 20, 3 to 20, 4 to 20, 4 to 18, 4 to 10, or 4 to 6 carbon atoms. Acrylate monomers such as alkyl acrylate monomers form homopolymers that are generally less rigid than those derived from their alkyl methacrylate counterparts.

Preferably, the composition and respective T_{g} of the A and B blocks provides for a non-tacky base layer. A base layer that is non-tacky is advantageous because it is easy to handle and manipulate. This, in turn, facilitates use of the base layer as a stand alone layer in manufacturing. Moreover, a non-tacky base layer also facilitates handling of the reflective film by the end user whenever the base layer is an exterior layer of the reflective film.

In some base layer compositions, the block copolymer is an ABA triblock (meth)acrylate block copolymer with an A block polymeric unit derived from a methacrylate monomer and a B block polymeric unit derived from an acrylate monomer. For example, the A block polymeric units can be derived from an alkyl methacrylate monomer and the B block polymer unit can be derived from an alkyl acrylate monomer.

In some more specific examples, the A blocks are derived from an alkyl methacrylate with an alkyl group having 1 to 6, 1 to 4, 1 to 3, or 1 to 2 carbon atoms and the B block is derived from an alkyl acrylate with an alkyl group having 3 to 20, 4 to 20, 4 to 18, 4 to 10, 4 to 6, or 4 carbon atoms. For example, the A blocks can be derived from methyl methacrylate and the B block can be derived from an alkyl acrylate with an alkyl group having 4 to 10, 4 to 6, or 4 carbon atoms.

In a more specific example, the A blocks can be derived from methyl methacrylate and the B block can be derived from n-butyl acrylate. That is, the A blocks are poly(methyl methacrylate) and the B block is poly(n-butyl acrylate).

Optionally, the weight percent of the B block equals or exceeds the weight percent of the A blocks in the block copolymer. Assuming that the A block is a hard block and the B block is a soft block, higher amounts of the A block tend to increase the modulus of the block copolymer. If the amount of the A block is too high, however, the morphology of the block copolymer may be inverted from the desirable arrangement where the B block forms a continuous phase and the block copolymer is an elastomeric material. That is, if the amount of the A block is too high, the copolymer tends to have properties more similar to a thermoplastic material than to an elastomeric material.

Preferably, the block copolymer contains 10 to 50 weight percent of the A block polymeric units and 50 to 90 weight percent of the B block polymeric units. For example, the block copolymer can contain 10 to 40 weight percent of the A block polymeric units and 60 to 90 weight percent of the B block polymeric units, 10 to 35 weight percent of the A block polymeric units and 65 to 90 weight percent of the B block polymeric units, 15 to 50 weight percent of the A block polymeric units and 50 to 85 weight percent of the B block polymeric units, 15 to 35 weight percent of the A block polymeric units and 65 to 85 weight percent of the B block polymeric units, 10 to 30 weight percent of the A block polymeric units and 70 to 90 weight percent of the B block polymeric units, 15 to 30 weight percent of the A block polymeric units and 70 to 85 weight percent of the B block polymeric units, 15 to 25 weight percent of the A block polymeric units and 75 to 85 weight percent of the B block polymeric units, or 10 to 20 weight percent of the A block polymeric units and 80 to 90 weight percent of the B block polymeric units.

The block copolymers can have any suitable molecular weight. In some embodiments, the molecular weight of the block copolymer is at least 2,000 g/mole, at least 3,000 g/mole, at least 5,000 g/mole, at least 10,000 g/mole, at least 15,000 g/mole, at least 20,000 g/mole, at least 25,000 g/mole, at least 30,000 g/mole, at least 40,000 g/mole, or at least 50,000 g/mole. In some embodiments, the molecular weight of the block copolymer is no greater than 500,000 g/mole, no greater than 400,000 g/mole, no greater than 200,000 g/mole, no greater than 100,000 g/mole, no greater than 50,000 g/mole, or no greater than 30,000 g/mole.

For example, the molecular weight of the block copolymer can be in the range of 1,000 to 500,000 g/mole, in the range of 3,000 to 500,000 g/mole, in the range of 5,000 to 100,000 g/mole, in the range of 5,000 to 50,000 g/mole, or in the range of 5,000 to 30,000 g/mole.

The molecular weight is typically expressed as the weight average molecular weight. Any known technique can be used to prepare the block copolymers. In some methods of preparing the block copolymers, iniferters are used as described in European Patent No. EP 349 232 (Andrus et al.). However, for some applications, methods of preparing block copolymers that do not involve the use of iniferters may be preferred because iniferters tend to leave residues that can be problematic especially in photo-induced polymerization reactions.

For example, the presence of thiocarbamate, which is a commonly used iniferter, may cause the resulting block copolymer to be more susceptible to weather-induced degradation. The weather-induced degradation may result from the relatively weak carbon-sulfur link in the thiocarbamate residue. The presence of thiocarbamate can often be detected, for example, using elemental analysis or mass spectroscopy. Thus, in some applications, it is desirable that the block copolymer is prepared using other techniques that do not result in the formation of this weak carbon-sulfur link.

Some suitable methods of making the block copolymers are living polymerization methods. As used herein, the term “living polymerization” refers to polymerization techniques, process, or reactions in which propagating species do not undergo either termination or transfer. If additional monomer is added after 100 percent conversion, further polymerization can occur.

The molecular weight of the living polymer increases linearly as a function of conversion because the number of propagating species does not change. Living polymerization methods include, for example, living free radical polymerization techniques and living anionic polymerization techniques. Specific examples of living free radical polymerization reactions include atom transfer polymerization reactions and reversible addition-fragmentation chain transfer polymerization reactions.

Block copolymers prepared using living polymerization methods tend to have well-controlled blocks. As used herein, the term “well-controlled” in reference to the method of making the blocks and the block copolymers means that the block polymeric units have at least one of the following characteristics: controlled molecular weight, low polydispersity, well-defined blocks, or blocks having high purity. Some blocks and block copolymers have a well-controlled molecular weight that is close to the theoretical molecular weight.

The theoretical molecular weight refers to the calculated molecular weight based on the molar charge of monomers and initiators used to form each block. Well-controlled blocks and block copolymers often have a weight average molecular weight (M_{w}) that is about 0.8 to 1.2 times the theoretical molecular weight or about 0.9 to 1.1 times the theoretical molecular weight. As such, the molecular weight of the blocks and of the total block can be selected and prepared.

Some blocks and block copolymers have low polydispersity. As used herein, the term “polydispersity” is a measure of the molecular weight distribution and refers to the weight average molecular weight (M_{w}) divided by the number average molecular weight (Mₙ) of the polymer. Materials with the same molecular weight have a polydispersity of 1.0 while materials with multiple molecular weights have a polydispersity greater than 1.0. The polydispersity can be determined, for example, using gel permeation chromatography. Well-controlled blocks and block copolymers often have a polydispersity of 2.0 or less, 1.5 or less, or 1.2 or less.

Some block copolymers have well-defined blocks. That is, the boundaries between the A blocks and the continuous phase containing the B blocks are well defined. These well-defined blocks have boundaries that are essentially free of tapered structures. As used herein, the term “tapered structure” refers to a structure derived from monomers used for both the A and B blocks.

Tapered structures can increase mixing of the A block phase and the B block phase leading to decreased overall cohesive strength of the block copolymer or base layer containing the block copolymer. Block copolymers made using methods such as living anionic polymerization tend to result in boundaries that are free or essentially free of tapered structures.

The distinct boundaries between the A blocks and the B block often results in the formation of physical crosslinks that can increase overall cohesive strength without the need for chemical crosslinks. In contrast to these well-defined blocks, some block copolymers prepared using iniferters have less distinct blocks with tapered structures.

Optionally, the A blocks and B blocks have high purity. For example, the A blocks can be essentially free or free of segments derived from monomers used for the preparation of the B blocks. Similarly, B blocks can be essentially free or free of segments derived from monomers used for the preparation of the A blocks.

Living polymerization techniques typically lead to more stereoregular block structures than blocks prepared using non-living or pseudo-living polymerization techniques (e.g., polymerization reactions that use iniferters). Stereoregularity, as evidenced by highly syndiotactic structures or isotactic structures, tends to result in well-controlled block structures and tends to influence the glass transition temperature of the block.

For example, syndiotactic poly(methyl methacrylate) (PMMA) synthesized using living polymerization techniques can have a glass transition temperature that is about 20 degrees Celsius to about 25 degrees Celsius higher than a comparable PMMA synthesized using conventional (i.e., non-living) polymerization techniques. Stereoregularity can be detected, for example, using nuclear magnetic resonance spectroscopy. Structures with greater than about 75 percent stereoregularity can often be obtained using living polymerization techniques.

When living polymerization techniques are used to form a block, the monomers are generally contacted with an initiator in the presence of an inert diluent (or solvent). The inert diluent can facilitate heat transfer and mixing of the initiator with the monomers. Although any suitable inert diluent can be used, saturated hydrocarbons, aromatic hydrocarbons, ethers, esters, ketones, or a combination thereof are often selected.

Exemplary diluents include, but are not limited to, saturated aliphatic and cycloaliphatic hydrocarbons such as hexane, octane, cyclohexane, and the like; aromatic hydrocarbons such as toluene; and aliphatic and cyclic ethers such as dimethyl ether, diethyl ether, tetrahydrofuran, and the like; esters such as ethyl acetate and butyl acetate; and ketones such as acetone, methyl ethyl ketone, and the like.

When the block copolymers are prepared using living anionic polymerization techniques, the simplified structure A-M represents the living A block where M is an initiator fragment selected from a Group I metal such as lithium, sodium, or potassium. For example, the A block can be the polymerization reaction product of a first monomer composition that includes methacrylate monomers according to Formula (I). A second monomer composition that includes the monomers used to form the B block can be added to A-M resulting in the formation of the living diblock structure A-B-M. For example, the second monomer composition can include monomers according to Formula (II). The addition of another charge of the first monomer composition, which can include monomers according to Formula (I), and the subsequent elimination of the living anion site can result in the formation of triblock structure A-B-A. Alternatively, living diblock A-B-M structures can be coupled using difunctional or multifunctional coupling agents to form the triblock structure A-B-A copolymers or (A-B)[n]-star block copolymers.

Any initiator known in the art for living anionic polymerization reactions can be used. Typical initiators include alkali metal hydrocarbons such as organo lithium compounds (e.g., ethyl lithium, n-propyl lithium, iso-propyl lithium, n-butyl lithium, sec-butyl lithium, tert-octyl lithium, n-decyl lithium, phenyl lithium, 2-naphthyl lithium, A-butylphenyl lithium, 4-phenylbutyl lithium, cyclohexyl lithium, and the like). Such initiators can be useful in the preparation of living A blocks or living B blocks.

For living anionic polymerization of (meth)acrylates, the reactivity of the anion can be tempered by the addition of complexing ligands selected from materials such as crown ethers, or lithium ethoxylates. Suitable difunctional initiators for living anionic polymerization reactions include, but are not limited to, 1,1,4,4-tetraphenyl-1,4-dilithiobutane; 1,1,4,4-tetraphenyl-1,4-dilithioisobutane; and naphthalene lithium, naphthalene sodium, naphthalene potassium, and homologues thereof.

Other suitable difunctional initiators include dilithium compounds such as those prepared by an addition reaction of an alkyl lithium with a divinyl compound. For example, an alkyl lithium can be reacted with 1,3-bis(1-phenylethenyl)benzene or m-diisopropenylbenzene.

For living anionic polymerization reactions, it is usually advisable to add the initiator in small quantities (e.g., a drop at a time) to the monomers until the persistence of the characteristic color associated with the anion of the initiator is observed. Then, the calculated amount of the initiator can be added to produce a polymer of the desired molecular weight. The preliminary addition of small quantities often destroys contaminants that react with the initiator and allows better control of the polymerization reaction.

The polymerization temperature used depends on the monomers being polymerized and on the type of polymerization technique used. Generally, the reaction can be carried out at a temperature of about −100 degrees Celsius to about 150 degrees Celsius. For living anionic polymerization reactions, the temperature is often about −80 degrees Celsius to about 20 degrees Celsius. For living free radical polymerization reactions, the temperature is often about 20 degrees Celsius to about 150 degrees Celsius. Living free radical polymerization reactions tend to be less sensitive to temperature variations than living anionic polymerization reactions.

Methods of preparing block copolymers using living anionic polymerization methods are further described, for example, in U.S. Pat. No. 6,734,256 (Everaerts et al), U.S. Pat. No. 7,084,209 (Everaerts et al), U.S. Pat. No. 6,806,320 (Everaerts et al), and U.S. Pat. No. 7,255,920 (Everaerts et al.). This polymerization method is further described, for example, in U.S. Pat. No. 6,630,554 (Hamada et al.) and U.S. Pat. No. 6,984,114 (Kato et al.) as well as in Japanese Patent Application Kokai Publication Nos. Hei 11-302617 (Uchiumi et al.) and 11-323072 (Uchiumi et al.)

In general, the polymerization reaction is carried out under controlled conditions so as to exclude substances that can destroy the initiator or living anion. Typically, the polymerization reaction is carried out in an inert atmosphere such as nitrogen, argon, helium, or combinations thereof. When the reaction is a living anionic polymerization, anhydrous conditions may be necessary.

Suitable block copolymers can be purchased from Kuraray Co., LTD. (Tokyo, Japan) under the trade designation LA POLYMER. Some of these block copolymers are triblock copolymers with poly(methyl methacrylate) endblocks and a poly(n-butyl acrylate) midblock. In some embodiments, more than one block copolymer is included in the base layer composition. For example, multiple block copolymers with different weight average molecular weights or multiple block copolymers with different block compositions can be used.

The use of multiple block copolymers with different weight average molecular weights or with different amounts of the A block polymeric units can, for example, improve the shear strength of the base layer composition.

If multiple block copolymers with different weight average molecular weights are included in the base layer composition, the weight average molecular weights can vary by any suitable amount. In some instances, the molecular weights of a first block copolymer can vary by at least 25 percent, at least 50 percent, at least 75 percent, at least 100 percent, at least 150 percent, or at least 200 percent from a second block copolymer having a larger weight average molecular weight.

The block copolymer mixture can contain 10 to 90 weight percent of a first block copolymer and 10 to 90 weight percent of a second block copolymer having a larger weight average molecular weight, 20 to 80 weight percent of the first block copolymer and 20 to 80 weight percent of the second block copolymer having the larger weight average molecular weight, or 25 to 75 weight percent of the first block copolymer and 25 to 75 weight percent of the second block copolymer having the larger weight average molecular weight.

If multiple block copolymers with different concentrations of the A block polymeric units are included in the base layer composition, the concentrations can differ by any suitable amount. In some instances, the concentration can vary by at least 20 percent, at least 40 percent, at least 60 percent, at least 80 percent, or at least 100 percent.

The block copolymer mixture can contain 10 to 90 weight percent of a first block copolymer and 10 to 90 weight percent of a second block copolymer having a greater amount of the A block or 20 to 80 weight percent of the first block copolymer and 20 to 80 weight percent of the second block copolymer having the greater amount of the A block or 25 to 75 weight percent of the first block copolymer and 25 to 75 weight percent of the second block copolymer having the greater amount of the A block.

### Metallic Layer Components

The provided reflective articles comprise one or more metallic layers. Besides providing a high degree of reflectivity, such articles can also provide manufacturing flexibility. Optionally, the metallic layer may be applied onto a relatively thin organic tie layer or inorganic tie layer, which is in turn situated on a polymeric base layer.

The metallic layers contemplated for the provided reflective articles have smooth, reflective metal surfaces that can also be specular surfaces. As used herein, “specular surfaces” refer to surfaces that induce a mirror-like reflection of light in which the direction of incoming light and the direction of outgoing light form the same angle with respect to the surface normal. Any reflective metal may be used for this purpose, although preferred metals include silver, gold, aluminum, copper, nickel, and titanium. Of these, silver, aluminum and gold are particularly preferred.

Optionally, one or more layers can also be added to alleviate the effects of corrosion on the reflective article. For example, a copper layer may be deposited onto the back side of a silver layer for use as a sacrificial anode to reduce corrosion of adjacent metallic layers.

A metallic layer can be deposited on the base layer using a variety of methods. Examples of suitable deposition techniques include physical vapor deposition via sputter coating, evaporation via e-beam or thermal methods, ion-assisted e-beam evaporation and combinations thereof. Metallic or ceramic mask or shuttering features may be used to limit the deposition to certain areas if so desired.

One particularly suitable deposition technique for forming metallic layers is physical vapor deposition (PVD) by sputtering. In this technique, atoms of the target are ejected by high-energy particle bombardment so that they can impinge onto a substrate to form a thin film. The high-energy particles used in sputter-deposition are generated by a glow discharge, or a self-sustaining plasma created by applying, for example, an electromagnetic field to argon gas.

In one exemplary method, the deposition process continues for a sufficient duration to build up a suitable layer thickness of the metallic layer on the base layer, thereby forming the metallic layer. As another option, other metals besides silver may be used. For example, metallic layers composed of a different metal may be similarly deposited by using a suitable target composed of that metal.

### Optional Reflective Film Components

### Random Copolymers

In some exemplary embodiments, the multilayer films may optionally include at least one random copolymer. As used herein, the term “random copolymer” refers to a polymeric material that includes at least two different polymeric units (or repeat units) that are covalently bonded to each other in a randomized fashion along the polymer backbone. Like block copolymers, random copolymers include two or more polymeric units that are chemically dissimilar. Moreover, the polymeric units of random copolymers are derived from two or more respective monoethylenically unsaturated monomers, and are associated with different respective glass transition temperatures. However, unlike block copolymers, random copolymers have polymeric units that are not segregated into discrete blocks, but rather homogenously interspersed with each other on a nanoscopic level.

Random copolymers also differ from block copolymers in their macroscopic properties. While block copolymers can microphase separate based on the insolubility of the A and B blocks, random copolymers have a homogenous microstructure. As a result, random copolymers display only a single glass transition temperature, while microphase-separated block copolymers display two or more glass transition temperatures.

The glass transition temperature of a random copolymer generally resides between the glass transition temperatures associated with its respective polymeric units. For example, a random copolymer of methyl methacrylate and n-butyl acrylate has a glass transition temperature residing between that of the corresponding poly(methyl methacrylate) and poly(n-butyl acrylate) homopolymers. If desired, the exact glass transition temperature can be approximated using various theoretical and empirical formulas based on the glass transition temperatures associated with the polymeric units and the relative weight or volume fraction of each component.

The random copolymers described herein include at least a first polymeric unit A and a second polymeric unit B. The A polymeric unit is the “hard,” rigid component, while the B polymeric unit is the “soft,” less rigid component. The A polymeric unit, when reacted to form a homopolymer, has a glass transition temperature of at least 50° C. The B polymeric unit, when reacted to form a homopolymer, has a glass transition temperature no greater than 20° C. In other words, the A polymeric unit is associated with a glass transition temperature of at least 50° C., while the B polymeric unit is associated with a glass transition temperature no greater than 20° C.

In exemplary random copolymers, the A polymeric unit is associated with a glass transition temperature of at least 60° C., at least 80° C., at least 100° C., or at least 120° C., while the B polymeric unit is associated with a glass transition temperature no greater than 10° C., no greater then 0° C., no greater than −5° C., or no greater than −10° C.

The A polymeric units are generally associated with homopolymers that are thermoplastic materials, while the B polymeric units are generally associated with homopolymers that are elastomeric materials. Further, the solubility parameters associated with the A and B polymeric units are sufficiently different that the respective A and B homopolymers would not be miscible in each other. As a result of its randomized polymer architecture, however, the random copolymer exhibits a homogenous microstructure at all compositions.

Exemplary chemical structures and characteristics of the A and B polymeric units are similar to those previously described for the A block and B block polymeric units, and thus shall not be repeated here.

The weight percent of the A polymeric units generally exceeds the weight percent of the B polymeric units in the random copolymer. Higher amounts of the A polymeric unit tends to increase the overall modulus of the random copolymer. At the same time, higher amounts of the A polymeric block also tends to reduce the tackiness of the random copolymer at ambient temperatures. The single or multilayer film including the random copolymer may be either tacky or non-tacky. However, it is preferable that the single or multilayer film is non-tacky for the same reasons given before concerning single or multilayer films that include block copolymers.

The random copolymer typically contains 60 to 95 weight percent of the A polymeric units and 5 to 40 weight percent of the B polymeric units. For example, the block copolymer can contain 60 to 90 weight percent of the A polymeric units and 10 to 40 weight percent of the B polymeric units, 60 to 85 weight percent of the A polymeric units and 15 to 40 weight percent of the B polymeric units, 65 to 95 weight percent of the A polymeric units and 5 to 35 weight percent of the B polymeric units, 65 to 90 weight percent of the A polymeric units and 10 to 35 weight percent of the B polymeric units, 65 to 85 weight percent of the A polymeric units and 15 to 35 weight percent of the B polymeric units, 70 to 95 weight percent of the A polymeric units and 5 to 30 weight percent of the B polymeric units, 70 to 90 weight percent of the A polymeric units and 10 to 20 weight percent of the B polymeric units, or 70 to 85 weight percent of the A polymeric units and 15 to 30 weight percent of the B polymeric units.

Like the block copolymers described previously, the random copolymers can have any suitable molecular weight. Exemplary molecular weights have already been enumerated in detail for block copolymers and similarly apply here for random copolymers. Additionally, random copolymers having low polydispersity are also contemplated. In preferred embodiments, the random copolymer has a polydispersity of 2.0 or less, 1.5 or less, or 1.2 or less.

Suitable methods of making the random copolymers include living polymerization methods, including the living anionic and living free radical polymerization techniques previously described. While the synthesis of block copolymers generally involves sequential addition of the A and B monomers, however, the synthesis of random copolymers generally involves adding the initiator to a stirred solution containing both the A and B monomers or simultaneously introducing both the A and B monomers into a stirred solution of the initiator. Advantageously, these methods tend to produce random copolymers with controlled molecular weight, low polydispersity, and/or high purity. Conventional, non-living, free-radical polymerization techniques may also be used to prepare the random copolymers. Suitable random copolymers are also commercially available from Dow Chemical Company (Midland, Mich.), BASF SE (Ludwigshafen, Germany), and The Polymer Source, Inc. (Montreal, Canada).

In some embodiments, two or more random copolymers may be included in the single or multilayer film compositions described herein. For example, random copolymers having different weight average molecular weights or different compositions of the A and B polymeric units may be used. Optionally, the two or more random copolymers are present as discrete layers within in the single or multilayer film. Alternatively, the two or more random copolymers are blended together to provide a homogenous microstructure. If a blend is contemplated, it is preferable that any differences in composition are not so large that the copolymers phase separate from each other. Advantageously, a combination of two or more random copolymers can be used to tailor the shear strength of the single or multilayer film composition.

In some embodiments, the differences in molecular weight and/or differences in composition of the two or more random copolymers are similar to those previously enumerated with respect to block copolymers. As such, this description shall not be repeated here.

### Ultraviolet Light Absorbers and Hindered Amine Light Stabilizers

Overall, the multilayer reflective film is capable, in some exemplary embodiments, of providing high hardness and weatherability, excellent coatability (or sticking coefficient), and vacuum ultraviolet radiation stability. In certain exemplary embodiments, additives such as ultraviolet stabilizers, hindered amine light stabilizers (HALS), antioxidants and the like are included in the single layer film 100 or in one or both of the outer layers 102′ and 102″ of a dual layer 100′ or multilayer 100″ film. Preferably, the at least one interior layer 108 having a composition 103 is kept substantially free of these additives to avoid adhesion issues that could arise from segregation of ultraviolet stabilizers, HALS, antioxidants and other additives to the surface to be coated.

Thus, in some exemplary embodiments of any of the foregoing films, the film further includes at least one ultraviolet (UV) light absorber in an amount from 0.1 wt. % to 10 wt. %. In certain such exemplary embodiments, the film further includes at least one hindered amine light stabilizer (HALS) in an amount from 0.1 wt. % to 1 wt. %. Optionally, the UV light absorber is present in an amount from 0.5 wt. % to 5 wt. %.

In some exemplary dual 100′ or multilayer 100″ film embodiments, one or both of the outer layers 102′ and 102″ is comprised of poly(methyl methacrylate) and contains an amount of an ultraviolet light absorber ranging from 0.5 percent to 3.0 percent by weight, based on the total weight of the poly(methyl methacrylate) and absorber.

In additional exemplary embodiments of any of the foregoing films, the film further includes a multiplicity of inorganic nanoparticulates having a median particle diameter of less than one micrometer. In some such exemplary embodiments, the inorganic nanoparticulates are metal oxide particulates selected from titanium dioxide, aluminum oxide, silicon dioxide, indium oxide, tin oxide, zinc oxide, zirconium oxide, and combinations thereof. The inorganic nanoparticulates may be distributed, preferably homogeneously distributed, throughout a single film layer, or included in one, any or all of the film layers of the multilayer 100″ film.

### Nanoparticulates

In additional exemplary embodiments of any of the foregoing multilayer reflective films 100, the reflective films 100 may further include a plurality of inorganic nanoparticulates having a median particle diameter of less than one micrometer. In some such exemplary embodiments, the inorganic nanoparticulates are metal oxide particulates selected from titanium dioxide, aluminum oxide, silicon dioxide, indium oxide, tin oxide, zinc oxide, zirconium oxide, and combinations thereof. The inorganic nanoparticulates may be distributed, preferably homogeneously distributed, throughout a single layer of the film 100, or included in one, any or all of the outer layers 330, 102, 220, 108, and/or 110 of a multilayer reflective film 100.

### Methods

Exemplary films of the present disclosure may be prepared, for example, using the apparatus and methods disclosed in U.S. Pat. No. 6,783,349, entitled “Apparatus for Making Multilayer Optical Films”, and U.S. Pat. No. 6,827,886, entitled “Method for Making Multilayer Optical Films”. Examples of additional layers or coatings suitable for use with exemplary films of the present disclosure are described in U.S. Pat. Nos. 6,368,699, and 6,459,514 both entitled “Multilayer Polymer Film with Additional Coatings or Layers”.

### Reflective Articles and Unexpected Results and Advantages

The disclosure also provides articles comprising any of the foregoing films. In certain such exemplary embodiments, the article is selected from a lighting element, a solar reflector, a mirror, a window, a graphic arts display, a sign, or a combination thereof. While these articles are generally intended for use in reflective applications, this should not be deemed to unduly limit the invention. For example, these articles are also contemplated for non-reflective uses such as in food storage or vapor barrier applications.

Preferably, the foregoing films and/or articles are visible light-transmissive or optically clear, exhibiting, in some exemplary embodiments, an average radiation transmission over the visible light portion of the radiation spectrum from 380 nm to 780 nm (Tᵥᵢₛ) of at least about 90%, measured along the normal axis. Additionally and more preferably, in some exemplary embodiments the foregoing films exhibit an average radiation transmission of at least 90% over the solar radiation wavelength range from 380 nm to 3,000 nm (Tₛₒₗₐᵣ).

The exemplary films and articles of the present disclosure, in some exemplary embodiments, advantageously provide high optical transmissivity and low haze and yellowing, good weatherability, good abrasion, scratch and crack resistance during to handling and cleaning, and good adhesion to other layers, for example, other (co)polymer layers, metal oxide layers, and metal layers applied to one or both major surfaces of the films when used as substrates, for example, in compact electronic display and/or solar energy applications.

While not wishing to be bound by any particular theory, it is presently believed that in a high vacuum process such as physical vapor deposition, vacuum ultraviolet radiation (having wavelengths below 165 nanometers) can induce chain scission at the surface of a poly(methyl methacrylate) top layer. This chain scission can, in turn, adversely affect the ability of the poly(methyl methacrylate) to adhere to adjacent metal layers deposited using such a process. In some exemplary embodiments, the single 100, dual 100′ or multilayer film 100″ can advantageously protect a poly(methyl methacrylate) surface. Since the film is less susceptible to chain scission, it can insulate the poly(methyl methacrylate) surface from the damaging effects of vacuum ultraviolet radiation.

The single or multilayer film 302 may provide, in some exemplary embodiments, additional benefits that promote adhesion during environmental exposure to temperature and humidity fluctuations. The rubbery B block permits diffusion of stress due to differential expansion in the stack associated with changes in temperature and humidity. Additionally, the disclosed block and random copolymers are also substantially less water permeable than poly(methyl methacrylate). Water adsorption can result in chemical or physical reduction in adhesive contact between the metal and adjacent polymer layer.

The thin tie layer 220 was found to provide surprisingly robust reflective films. The tie layer 220 appears to maintain adhesion between the poly(methyl methacrylate) and the metal by diffusing stress during environmental exposure. The stress diffusive properties of the disclosed block and random copolymers were found to be surprisingly effective in preventing delamination in the samples tested. Temperatures at the interface during deposition significantly exceed the T_{g} of the B block of the tie layer 220, which may permit rearrangement of the polymer at the interface to relax stresses induced by (1) temperature gradients across the stack, (2) unrelieved stresses in the deposited film, and (3) degradation reactions in tie layer 220 during deposition.

In some exemplary embodiments, the tie layer 220 may provide additional benefits that promote adhesion during environmental exposure to temperature and humidity fluctuations. The rubbery B block permits diffusion of stress due to differential expansion in the stack associated with changes in temperature and humidity. Additionally, the disclosed block and random copolymers are also substantially less water permeable than poly(methyl methacrylate). Water adsorption can result in chemical or physical reduction in adhesive contact between the metal and adjacent polymer layer.

Optionally, the multilayer reflective film is part of an assembly or article which is rigidly held by a suitable underlying support structure. For example, the article can be comprised in one of the many mirror panel assemblies as described in U.S. Patent Application Publication No. US 2012/0160324 A1.

Exemplary embodiments of reflective multilayer films, methods of making the films, and articles incorporating the films, have been described above and are further illustrated below by way of the following Examples, which are not to be construed in any way as imposing limitations upon the scope of the present invention. On the contrary, it is to be clearly understood that resort may be had to various other embodiments, modifications, and equivalents thereof which, after reading the description herein, may suggest themselves to those skilled in the art without departing from the spirit of the present disclosure and/or the scope of the appended claims.

### EXAMPLES

These examples are merely for illustrative purposes and are not meant to be limiting on the scope of the appended claims. Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in their respective testing measurements. At the very least, and not as an attempt to limit the application of the doctrine of equivalents to the scope of the claims, each numerical parameter should at least be construed in light of the number of reported significant digits and by applying ordinary rounding techniques.

### Materials

All parts, percentages, ratios, and the like in the examples and the rest of the specification are by weight, unless noted otherwise. Solvents and other reagents used may be obtained from Sigma-Aldrich Chemical Company (Milwaukee, Wis.) unless otherwise noted.

TABLE 1
Materials

| Material | Supplier |
|---|---|
| Poly(methyl methacrylate) (PMMA) resin | Plaskolite, Inc., |
| CP-80 | Columbus, OH |
| Poly(butyl acrylate) Block copolymer (PnBA): | Kuraray Co., Ltd., |
| LA 4285 | Tokyo, Japan |
| LAF820 (80:20 w/w mix of LA4285 and PMMA) | |

### Test Methods

### Specularity

A D&S Portable Specular Reflectometer Model 15R-USB (available from Device and Services, Co., Dallas Tex.) was used for specularity measurement. The instrument uses a 660 manometer LED and collimating optics to produce a 10 mm. diameter source beam. The reflected beam is focused through one of three thumbwheel selectable apertures. Standard acceptance angles are 15, 25 and 46 milliradians. We used 15 mrad acceptance angle for our measurements.

### Tape Adhesion

Adhesion of metal to the polymer was tested by simple tape test method using magic tape (Catalogue #810) available from 3M company. A 5″ long piece of ½″ wide magic tape was adhered to the metal side of the sample with the help of a hand roller leaving a small tab on the end to use as a handle for peeling. Good contact of tape adhesive with metal was ensured by removing any air bubbles trapped between metal and tape. Tape was pulled of the sample manually at a high angle (150 to 180 degree) and slow pull rate (˜1 ft/min) in one single motion. The sample and tape both were examined for metal removal and calculating the area where metal was removal by tape.

### Preparation of Reflective Multilayer Films

### Example 1

### PnBA (LA 4285) on ¼″ Thick PMMA

The coating solution was made by dissolving PnBA (LA4285) in methyl ethyl ketone (MEK) in a pyrex beaker with magnetic stirring to create a 10 wt. % solids solution. The polymer was left stirring in MEK, on the magnetic stirrer, for several hours to obtain a clear solution.

The coating solution was applied at a thickness of 1 μm to a sheet of ¼″ clear PMMA (Clear Plexiglass Acrylic) obtained from Ridout Plastics using a Meyer rod.

After applying the solution the specimen was vapor coated in a high vacuum (low pressure) physical vapor deposition (PVD) coater in order to add the metallic layer and a TiO₂ tie layer. Up to six specimens were loaded at a time, in the rotating dome of the PVD coater, on six 12 inch (30.5 cm) diameter specimen holders, which were located near the edge of the dome and configured at 45 degree angles facing the point source. The point source had 4 pocket e-beam crucibles, each of 1.5 inch (3.8 cm) diameter. As is common for PVD coaters of this type, the coating dome was rotated on its central axis and each holder was also rotated on its individual central axis. This double rotation served to ensure uniform deposition of metal and metal oxides vapors from the hot point source.

Once the specimens were loaded, the coater was evacuated, first using a mechanical roughing pump and then using a cryogenic pump to reduce pressure to one millionth of a torr. At this pressure, the electron beam gun was turned on to pre-heat TiO₂ pellets in the first of the four crucibles. When an appropriate vapor pressure of TiO₂ was achieved, the shield between the heated crucible and the specimen holders was removed, allowing TiO₂ vapors to deposit on the rotating specimens. A 5 nm thick TiO₂ film was deposited, at the rate of 5 Angstroms/second, on the surface of the specimens. The rate of deposition and the thickness was measured using an INFICON brand crystal rate/thickness monitoring sensor and controller (Inficon, East Syracuse, N.Y.).

After depositing 5 nm of TiO₂, the shield was automatically inserted by the thickness monitoring system to completely stop vapors from reaching the specimens. Without breaking vacuum, the second crucible, holding 99.999% purity silver wire pieces, was moved in to place. The same procedure as that for TiO₂ deposition was repeated to deposit a 90 nm thick silver layer over the TiO₂ layer. Then a third crucible holding copper wire was moved into place, and a 30 nm thick copper layer was deposited over the silver layer. Finally, the coater was backfilled slowly with dry nitrogen, and the specimens were carefully removed. An additional sheet of uncoated ¼″ PMMA was also vapor coated as described above, for use as a control.

After vapor coating the specimens, their dry adhesion was tested. Dry adhesion test results for PnBA coated samples are given in Table 2, and those for control samples are given in Table 3.

### Example 2

### PnBA (LA 4285) on Polyurethane Film

The coating solution was made as described in Example 1.

The coating solution was applied at a thickness of 1 μm to a polyurethane film, (obtained from 3M Company, St. Paul, Minn.) using a Meyer rod.

After applying the solution the specimen was vapor coated as described in example 1. An additional sheet of uncoated polyurethane film was also vapor coated, as described in example 1, for use as a control.

After vapor coating the specimens, their dry adhesion was tested. Dry adhesion test results for PnBA coated samples are given in Table 2, and those for control samples are given in Table 3.

### Example 3

### PnBA (LA 4285) on ¼″ Thick Polycarbonate

The coating solution was made as described in Example 1.

The coating solution was applied at a thickness of 1 μm to a ¼″ sheet of polycarbonate (obtained from 3M Company, St. Paul, Minn.) using a Meyer rod.

After applying the solution the specimen was vapor coated as described in example 1. An additional sheet of uncoated ¼″ polycarbonate was also vapor coated, as described in example 1, for use as a control.

After vapor coating the specimens, their dry adhesion was tested. Dry adhesion test results for PnBA coated samples are given in Table 2, and those for control samples are given in Table 3.

TABLE 2
PnBA Sample Dry Adhesion

| | Percentage | Layer of |
|---|---|---|
| Sample | Removed | Separation |
| Polyurethane Film, “SGHG” | 10 | Cu/Ag |
| Polyurethane Film, “Clear Coat” | 5 | Cu/Ag |
| ¼″ Plexiglass | 0 | NA |
| ¼″ Polycarbonate | 0 | NA |
| Zeonar Film | 100 | Cu/Ag |

TABLE 3
Control (Non-PnBA) Sample Dry Adhesion

| | Instron Force | |
|---|---|---|
| | Required | Layer of |
| Sample | (lb_{f}/half inch) | Separation |
| Polyurethane Film, “SGHG” | 98 | Cu/Ag |
| Polyurethane Film, “Clear Coat” | 85 | Cu/Ag |
| ¼″ Plexiglass | 98 | Cu/Ag |
| ¼″ Polycarbonate | 15 | Cu/Ag |
| Zeonar Film | 100 | Cu/Ag |

While the specification has described in detail certain exemplary embodiments, it will be appreciated that those skilled in the art, upon attaining an understanding of the foregoing, may readily conceive of alterations to, variations of, and equivalents to these embodiments. Accordingly, it should be understood that this disclosure is not to be unduly limited to the illustrative embodiments set forth hereinabove. Furthermore, all publications, published patent applications and issued patents referenced herein are incorporated by reference in their entirety to the same extent as if each individual publication or patent was specifically and individually indicated to be incorporated by reference. Various exemplary embodiments have been described. These and other embodiments are within the scope of the following listing of disclosed embodiments.

1. An article comprising:
a substrate having a first major surface and a second major surface opposite the first major surface;
a smoothing layer adjoining the first major surface of the substrate and extending across at least a portion of the first major surface of the substrate, wherein the smoothing layer is non-tacky at ambient temperatures and comprises poly(methyl methacrylate) and a first block copolymer having at least two endblock polymeric units that are each derived from a first monoethylenically unsaturated monomer comprising a methacrylate, acrylate, styrene, or combination thereof, wherein each endblock has a glass transition temperature of at least 50 degrees Celsius; and at least one midblock polymeric unit that is derived from a second monoethylenically unsaturated monomer comprising a methacrylate, acrylate, vinyl ester, or combination thereof, wherein each midblock has a glass transition temperature no greater than 20 degrees Celsius;
a tie layer adjoining and extending across at least a portion of the second major surface of the substrate, the tie layer having a first major surface adjoining the second major surface of the substrate, and a second major surface opposite the first major surface of the tie layer, wherein the tie layer comprises a second block copolymer with at least two endblock polymeric units that are each derived from a first monoethylenically unsaturated monomer comprising a methacrylate, acrylate, styrene, or combination thereof, wherein each endblock has a glass transition temperature of at least 50 degrees Celsius; and at least one midblock polymeric unit that is derived from a second monoethylenically unsaturated monomer comprising a methacrylate, acrylate, vinyl ester, or combination thereof, wherein each midblock has a glass transition temperature no greater than 20 degrees Celsius; and
a metallic layer adjoining and extending across at least a portion of the second major surface of the tie layer.

2. The article of claim 1, further comprising at least one additional block copolymer having endblocks comprising poly(methyl methacrylate) and a midblock comprising poly(butyl acrylate), wherein the at least one additional block copolymer is compositionally distinct from at least one of the first block copolymer or the second block copolymer, further wherein the at least one additional block copolymer is present in one or both of the smoothing layer and the tie layer.

3. The article of claim 2, wherein at least one of the first block copolymer, the second block copolymer, or the at least one additional block copolymer contains an ultraviolet (UV) light absorber in an amount from 0.5 wt. % to 3.0 wt. %, based on the total weight of the first block copolymer and the UV light absorber, the second block copolymer and the UV light absorber, or the at least one additional block copolymer and the UV light absorber, respectively.

4. The article of claim 1, wherein each endblock of at least one of the first block copolymer, the second block copolymer, or the at least one additional block copolymer is comprised of poly(methyl methacrylate), and further wherein each midblock of at least one of the first block copolymer or the second block copolymer is comprised of poly(butyl acrylate).

5. The article of claim 3, wherein at least one of the first block copolymer, the second block copolymer, or the at least one additional block copolymer is comprised of from 30 wt. % to 80 wt. % endblocks, and from 20 wt. % to 70 wt. % midblocks, based on a total weight of the respective block copolymer.

6. The article of claim 5, wherein at least one of the first block copolymer, the second block copolymer, or the at least one additional block copolymer is comprised of from 50 wt. % to 70 wt. % endblocks, and from 30 wt. % to 50 wt. % midblocks, based on the total weight of the respective block copolymer.

7. The article of claim 1, wherein the first block copolymer is the same as the second block copolymer.

8. The article of claim 1, wherein the smoothing layer has a thickness no greater than 5 micrometers.

9. (canceled)

10. The article of claim 1, wherein the tie layer has a thickness no greater than 500 micrometers.

11. (canceled)

12. The article of claim 1, wherein the metallic layer has a thickness no greater than 500 nanometers.

13-14. (canceled)

15. The article of claim 1, wherein the tie layer further comprises a metal oxide, optionally wherein the metal oxide is selected from the group consisting of titanium dioxide, aluminum oxide, silicon dioxide, indium oxide, tin oxide, zinc oxide, zirconium oxide, and combinations thereof.

16. (canceled)

17. The article of claim 15, wherein the metal oxide is comprised of a plurality of metal oxide nanoparticulates dispersed in the tie layer optionally wherein the plurality of metal oxide nanoparticulates exhibit a median particle diameter no greater than 200 nm.

18-19. (canceled)

20. The article of claim 15, wherein the metallic layer comprises one or more metals selected from the group consisting of: silver, gold, aluminum, copper, nickel, and titanium.

21. The article of claim 20, wherein the metallic layer comprises a silver layer contacting the tie layer and a copper layer adjacent to the silver layer opposite the tie layer.

22. The article of claim 21, wherein the silver layer has a thickness from 70 to 130 nanometers, and the copper layer has a thickness from 20 to 40 nanometers.

23. The article of claim 15, wherein the article has an arcuate surface, further wherein the metallic layer extends across at least a portion of the arcuate surface.

24. A reflective article comprising:
a substrate having a first major surface and a second major surface opposite the first major surface;
a smoothing layer extending across at least a portion of the first major surface of the substrate, wherein the smoothing layer is non-tacky at ambient temperatures and comprises poly(methyl methacrylate) and a first block copolymer having at least two endblock polymeric units that are each derived from a first monoethylenically unsaturated monomer comprising a methacrylate, acrylate, styrene, or combination thereof, wherein each endblock has a glass transition temperature of at least 50 degrees Celsius; and at least one midblock polymeric unit that is derived from a second monoethylenically unsaturated monomer comprising a methacrylate, acrylate, vinyl ester, or combination thereof, wherein each midblock has a glass transition temperature no greater than 20 degrees Celsius;
a tie layer, the tie layer having a first major surface extending across at least a portion of the second major surface of the substrate, and a second major surface opposite the first major surface of the tie layer, wherein the tie layer comprises a second block copolymer with at least two endblock polymeric units that are each derived from a first monoethylenically unsaturated monomer comprising a methacrylate, acrylate, styrene, or combination thereof, wherein each endblock has a glass transition temperature of at least 50 degrees Celsius; and at least one midblock polymeric unit that is derived from a second monoethylenically unsaturated monomer comprising a methacrylate, acrylate, vinyl ester, or combination thereof, wherein each midblock has a glass transition temperature no greater than 20 degrees Celsius; and
a metallic layer extending across at least a portion of the second major surface of the tie layer.

25. The reflective article of claim 24, wherein the metallic layer comprises silver, and further wherein the reflective article exhibits a Specularity of at least 94% as measured using the Specularity Method defined herein.

26. A method of making a reflective article, comprising:
providing a substrate having a first major surface and a second major surface opposite the first major surface;
applying a smoothing layer to at least a portion of the first major surface of the substrate, wherein the smoothing layer is non-tacky at ambient temperatures and comprises poly(methyl methacrylate) and a first block copolymer having at least two endblock polymeric units that are each derived from a first monoethylenically unsaturated monomer comprising a methacrylate, acrylate, styrene, or combination thereof, wherein each endblock has a glass transition temperature of at least 50 degrees Celsius; and at least one midblock polymeric unit that is derived from a second monoethylenically unsaturated monomer comprising a methacrylate, acrylate, vinyl ester, or combination thereof, wherein each midblock has a glass transition temperature no greater than 20 degrees Celsius;
applying a tie layer to at least a portion of the second major surface of the substrate, the tie layer having a first major surface extending across at least a portion of the second major surface of the substrate, and a second major surface opposite the first major surface of the tie layer, wherein the tie layer comprises a second block copolymer with at least two endblock polymeric units that are each derived from a first monoethylenically unsaturated monomer comprising a methacrylate, acrylate, styrene, or combination thereof, wherein each endblock has a glass transition temperature of at least 50 degrees Celsius; and at least one midblock polymeric unit that is derived from a second monoethylenically unsaturated monomer comprising a methacrylate, acrylate, vinyl ester, or combination thereof, wherein each midblock has a glass transition temperature no greater than 20 degrees Celsius; and
applying a metallic layer to at least a portion of the second major surface of the tie layer, optionally wherein the first block copolymer is the same as the second block copolymer.

27-29. (canceled)

30. The method of claim 26, wherein applying the smoothing layer comprises physical vapor deposition (PVD) coating of the smoothing layer.
